(19) United States
(12) Patent Application Publication
(10) Pub. No.: US 2013/0109288 A1
(43) Pub. Date: May 2, 2013

(54) FAN MODULE AND CABINET HAVING THE SAME

(71) Applicant: XIAN-XIU TANG, Shenzhen City (CN)

(72) Inventor: XIAN-XIU TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/329,230

(22) Filed: Dec. 17, 2011

(30) Foreign Application Priority Data
Oct. 26, 2011 (CN) 201110329382.9

(51) Int. Cl. F24F 7/007; F04D 29/00; H05K 5/02

(52) U.S. Cl. 454/184; 454/338; 416/244 R

(57) ABSTRACT

A cabinet includes an enclosure and a fan module. The enclosure includes a first sidewall and a second sidewall opposite to the first sidewall. The fan module includes a bracket, a number of fans mounted to the bracket, a fixing member pivotably connected to a first end of the bracket, and a fixing portion formed on a second end of the bracket opposite to the first end. The fixing member is fixed to the first sidewall of the enclosure. When the bracket is rotated towards the second sidewall of the enclosure, the fixing portion engages with the second sidewall.

### BACKGROUND

1. Technical Field

The present disclosure relates to a cabinet having a fan module.

2. Description of Related Art

Fan modules are almost always mounted to a front end or a rear end of a cabinet, respectively aligning with a number of servers installed in the cabinet, to dissipate heat for the servers. When the servers need to be examined or repaired, the corresponding fan modules must be detached first, then the servers can be taken out, which is troublesome.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of a cabinet, wherein the cabinet includes a fan module.

FIG. 2 is an enlarged view of a circled portion II of FIG. 1.

FIG. 3 is similar to FIG. 2, but viewed from another perspective.

FIG. 4 is a partial, assembled, isometric view of FIG. 1, wherein the fan module is locked.

FIG. 5 is similar to FIG. 4, but the fan module is unlocked.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

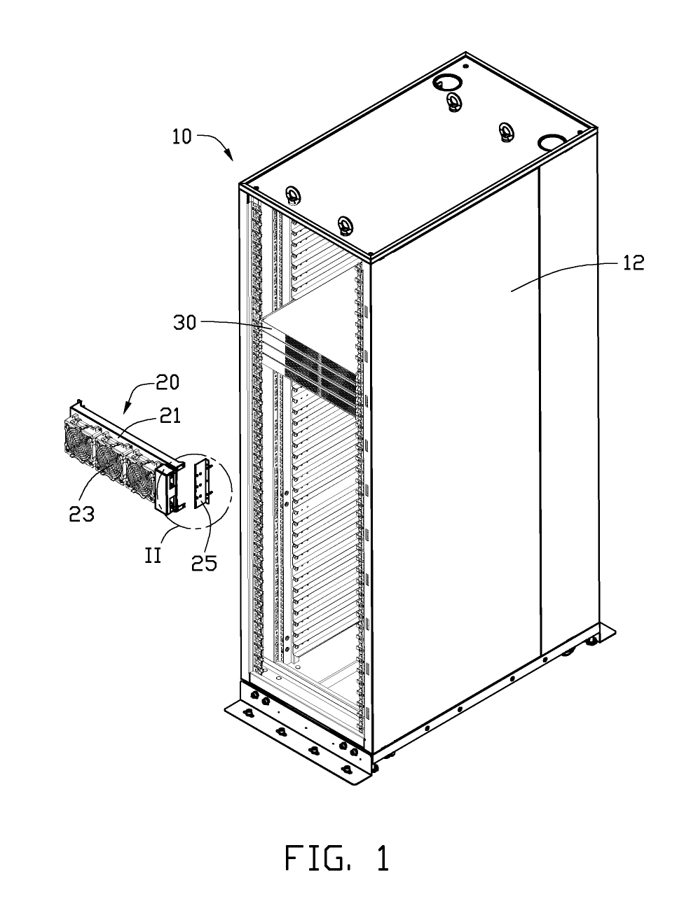

Referring to FIG. 1, an exemplary embodiment of a cabinet includes an enclosure 10 and a fan module 20.

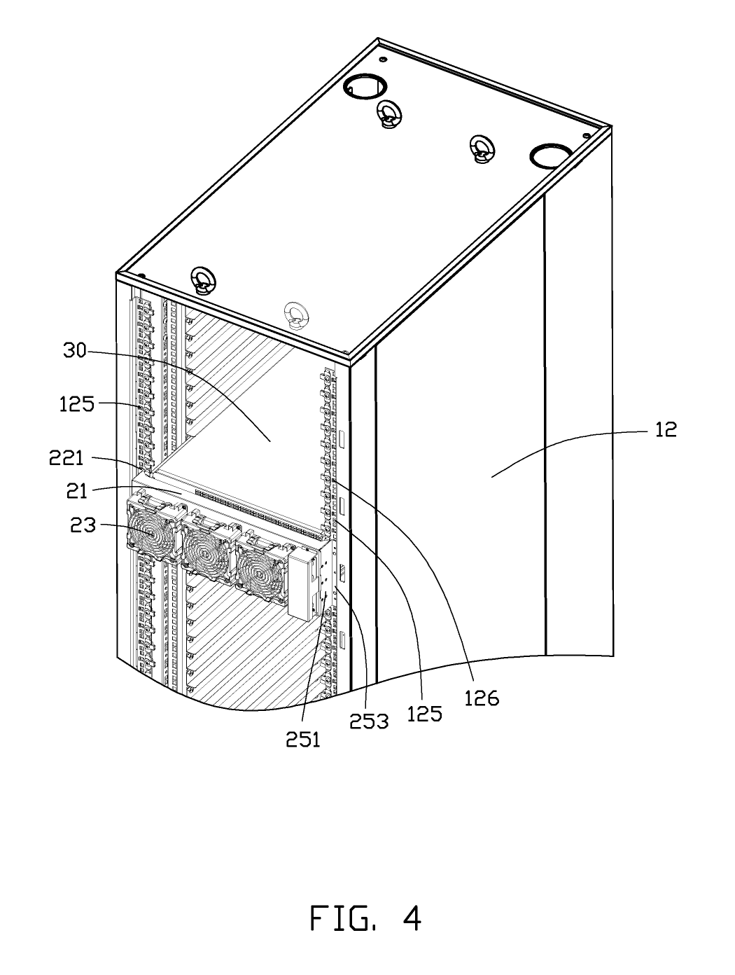

The enclosure 10 includes two opposite sidewalls 12. A plurality of servers 30 is mounted in the enclosure 10, between the sidewalls 12. A plurality of latching holes 125 and a plurality of fixing holes 126 (see FIG. 4) are defined in a first end of each sidewall 12.

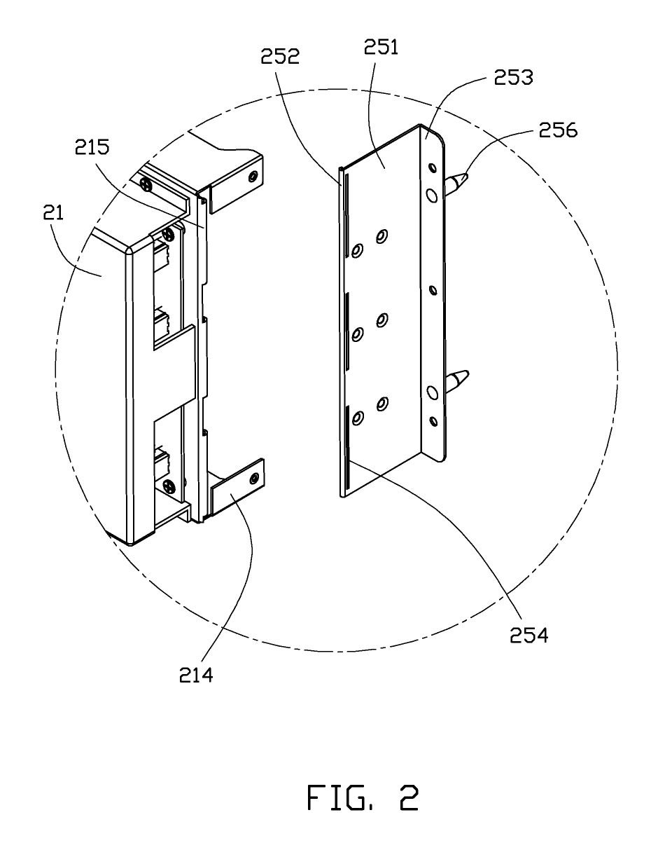

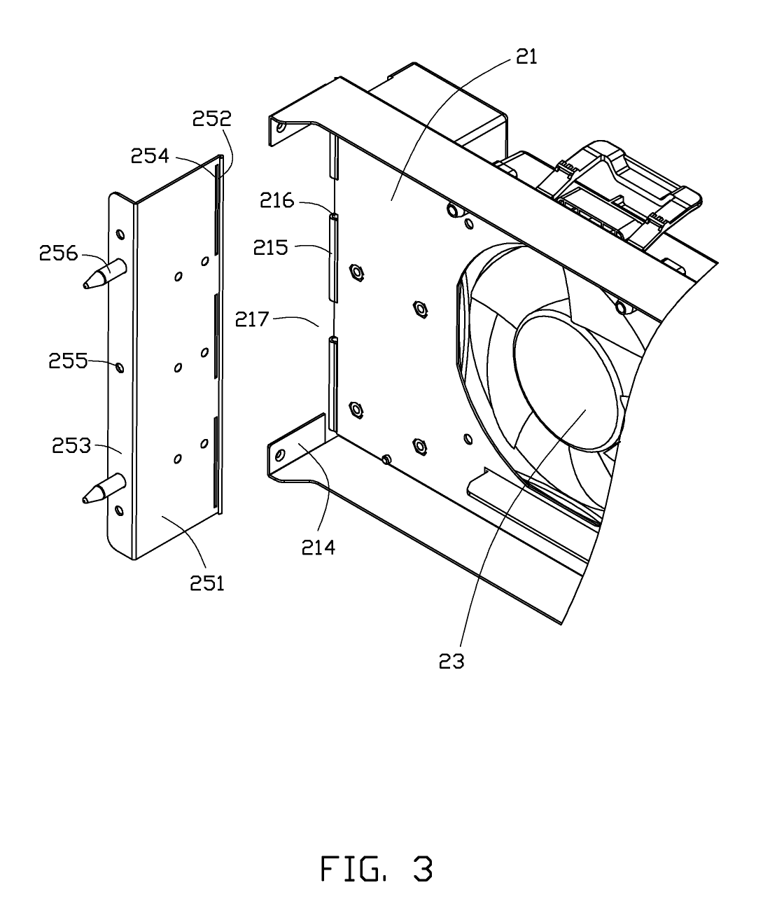

Referring to FIGS. 2, 3, and 5, the fan module 20 includes a substantially rectangular bracket 21, a plurality of fans 23 mounted to the bracket 21, and a fixing member 25. The bracket 21 defines a plurality of vents, respectively aligning with the fans 23. The bracket 21 includes a first end 214 and a second end 213 opposite to the first end 214. A fixing portion 22 is formed on the second end 213, and includes a fixing plate 221 extending out in a substantially perpendicular manner from a rear portion of an end surface of the second end 213, and two latches 223 protruding rearward from the fixing plate 221.

An opening 217 is defined in the first end 214 through the front and rear sides of the first end 214. A plurality of pivot portions 215 each having a substantially C-shaped cross section extends rearwards from the front side of the first end 214, with an opening of each pivot portion 215 facing the front side of the second end 213. A pivot hole 216 is bounded by each pivot portion 215 and the bracket 21. The fixing member 25 includes a plate 251, and a flange 253 extending in a substantially perpendicular manner from the rear side of the plate 251. A pivot 252 is formed on the front side of the plate 251 away from the flange 253. A plurality of through slots 254 is longitudinally defined in the plate 251 adjacent to the pivot 252. A plurality of through holes 255 is defined in the flange 253. Two fasteners 256 protrude rearward from the flange 253.

Referring to FIG. 4, in assembly, the plate 251 is attached to the first end 214, allowing the pivot 252 to engage in the pivot holes 216 from the openings of the pivot portions 215. The fixing member 25 is rotated rearwards around the pivot 252, to allow the distal sides of the pivot portions 215 to deform and respectively extend through the through slots 254. The distal sides of the pivot portions 215 are restored to engage with the plate 215. Thereby, the front end of the fixing member 25 is rotatably connected to the first end 214 of the bracket 21. The fan module 20 is assembled.

The fasteners 256 are engaged in two corresponding latching holes 125 of one of the sidewalls 12. A plurality of screws (not shown) is respectively extended through the through holes 255 and engaged in the corresponding fixing holes 126 of the sidewall 12. Thereby, the flange 253 is fixed to the sidewall 12. The bracket 21 is rotated towards the other sidewall 12, until the latches 223 engage in two corresponding latching holes 125 of the other sidewall 12. Thereby, the fan module 20 is locked to the enclosure 10. The fan module 20 aligns with the servers 30, and dissipates heat for the servers 30.

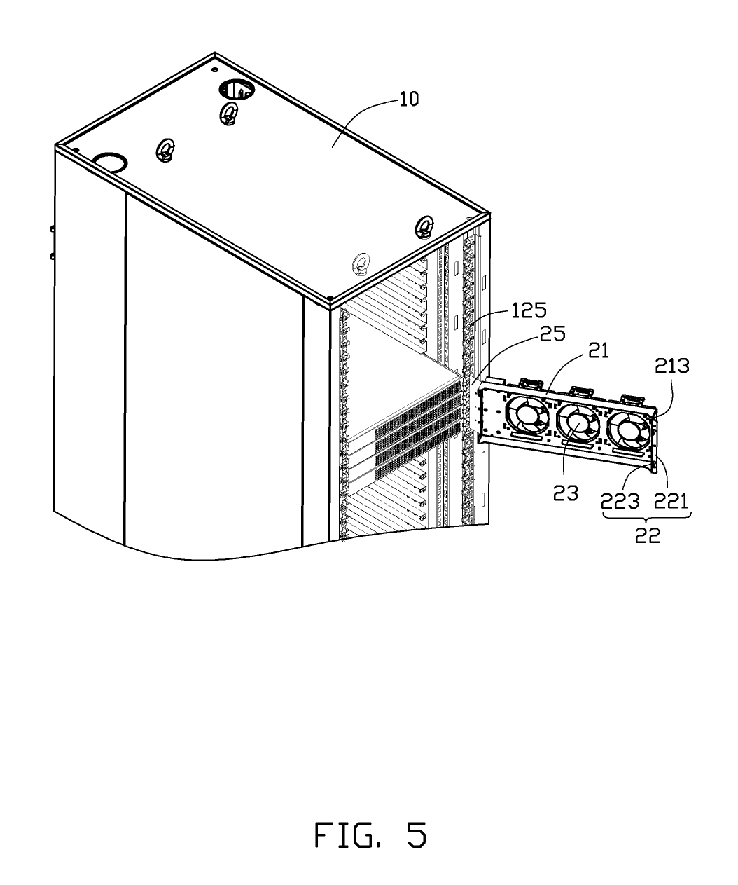

Referring to FIG. 5, to examine or repair the servers 30, the fixing plate 221 is pulled forwards, to allow the latches 223 to disengage from the corresponding latching holes 125. The fan module 20 is rotated away from the enclosure 10. The servers 30 can be taken out to be examined or repaired.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fan module, comprising:
a bracket;
a plurality of fans mounted to the bracket; and
a fixing member pivotably connected to a first end of the bracket, wherein the fixing member comprises a plate pivotably connected to the first end of the bracket with a front side, and a flange extending outwards in a substantially perpendicular manner from a rear side of the plate, a plurality of through holes is defined in the flange.

2. The fan module of claim 1, wherein a pivot portion having a substantially C-shaped cross section is formed on the first end of the bracket, a pivot hole is bounded by the pivot portion and the bracket, a pivot is formed on the front side of the plate of the fixing member, and a through slot is longitudinally defined in the plate adjacent to the pivot, the pivot is rotatably received in the pivot hole of the bracket, and a distal side of the pivot portion is extended through the through slot of the plate, to rotatably connect the fixing member to the bracket.

3. The fan module of claim 1, wherein a fixing plate extends out in a substantially perpendicular manner from a second end of the bracket away from the first end, two latches protrude from the fixing plate.

4. A cabinet, comprising:
an enclosure comprising a first sidewall and a second sidewall opposite to the first sidewall; and
a fan module comprising a bracket, a plurality of fans mounted to the bracket, a fixing member pivotably connected to a first end of the bracket, and a fixing portion formed on a second end of the bracket opposite to the first end, wherein the fixing member is fixed to the first sidewall of the enclosure, when the bracket is rotated towards the second sidewall of the enclosure, the fixing portion engages with the second sidewall.

5. The cabinet of claim 4, wherein an opening is defined in the first end of the bracket through front and rear sides of the first end, a pivot portion having a substantially C-shaped cross section is formed on the front side of the first end of the bracket, a pivot hole is bounded by the pivot portion and the bracket, the fixing member comprises a plate, a pivot is formed on a front end of the plate, and a through slot is longitudinally defined in the plate adjacent to the pivot, the pivot is rotatably received in the pivot hole of the bracket, and a distal side of the pivot portion is extended through the through slot of the plate, to rotatably connect the fixing member to the bracket.

6. The cabinet of claim 5, wherein two latching holes are defined in a front end of the first sidewall of the enclosure, the fixing member further comprises a flange extending outwards in a substantially perpendicular manner from a rear end of the plate, two fasteners protrude rearwards from a rear side of the flange, to respectively engage in the latching holes of the first sidewall.

7. The cabinet of claim 4, wherein two latching holes are defined in a front end of the second sidewall of the enclosure, the fixing portion of the bracket comprises a fixing plate extends out in a substantially perpendicular manner from a rear side of the second end of the bracket, two latches protrude from a rear side of the fixing plate, to respectively engage in the latching holes of the second sidewall.

8. The cabinet of claim 4, further comprising a plurality of servers mounted in the enclosure aligning with the fan module.
